(19) United States
(12) Patent Application Publication
(10) Pub. No.: US 2025/0126743 A1
(43) Pub. Date: Apr. 17, 2025

(54) Heat management in network switch

(71) Applicant: MELLANOX TECHNOLOGIES, LTD., Yokneam (IL)

(72) Inventors: Beeri Halachmi, Kohav Yair (IL); Nir Einati, Kfar Saba (IL); Vadim Pasternak, Modiin (IL)

(21) Appl. No.: 18/487,086

(22) Filed: Oct. 15, 2023

(51) Int. Cl. H05K 7/20; F04D 27/00

(52) U.S. Cl. CPC H05K 7/20209; F04D 27/004; F04D 27/007; H05K 7/20136

(57) ABSTRACT

An apparatus includes an interface and thermal management circuitry (TMC). The interface is configured to receive multiple measurements of multiple temperatures measured in multiple locations of an electronic system, respectively. The TMC is configured to: (a) convert the multiple measurements into multiple pulse width modulation (PWM) parameters, (b) calculate, based on at least the multiple PWM parameters, one or more PWM signals, and (c) control the multiple temperatures by applying the one or more PWM signals to one or more cooling devices.

### FIELD OF THE INVENTION

The present invention relates generally to electronic systems, and particularly to techniques for improving heat management in network switch systems.

### BACKGROUND OF THE INVENTION

Various techniques dissipating heat generated in switch systems are known in the art.

### SUMMARY OF THE INVENTION

An embodiment of the present invention that is described herein provides an apparatus including an interface and thermal management circuitry (TMC). The interface is configured to receive multiple measurements of multiple temperatures measured in multiple locations of an electronic system, respectively. The TMC is configured to: (a) convert the multiple measurements into multiple pulse width modulation (PWM) parameters, (b) calculate, based on at least the multiple PWM parameters, one or more PWM signals, and (c) control the multiple temperatures by applying the one or more PWM signals to one or more cooling devices.

In some embodiments, the TMC is configured to: (i) select a PWM parameter among the multiple PWM parameters, for example a maximal PWM parameter or a PWM parameter that meets a predetermined condition, and (ii) apply the selected PWM parameter to all of the cooling devices. In other embodiments, the TMC is configured to select a list of two or more components positioned at two or more of the locations, and the apparatus includes two or more temperature sensors coupled to the components, respectively, which are configured to perform the measurements of the temperatures in the components on the list, respectively. In yet other embodiments, the interface is configured to receive an error signal indicative of an error in at least one of: (i) one or more of the cooling devices, and (ii) one or more of the temperature sensors, and the TMC is configured to adjust at least one of the PWM signals responsively to the error.

In some embodiments, the multiple temperature sensors include first and second temperature sensors to perform first and second measurements, respectively, among the multiple measurements, and the TMC includes a controller, which is configured to define: (i) for the first temperature sensor, a first frequency of the first measurements, and (ii) for the second temperature sensor, a second frequency of the second measurements, different from the first frequency. In other embodiments, the TMC includes a controller, which is configured to calculate a ratio between the multiple PWM parameters and multiple parameters of the one or more cooling devices. In yet other embodiments, at least one of the cooling devices includes a fan, at least a parameter among the multiple parameters includes a rotation speed of the fan, and the controller is configured to calculate the ratio between the rotation speed of the fan and a corresponding PWM parameter among the multiple PWM parameters.

In some embodiments, the apparatus includes (i) multiple fans controlled to operate at multiple rotation speeds, respectively, (ii) multiple components located in at least some of the multiple locations, and (iii) a power supply unit (PSU) to supply power to at least some of the multiple components, the PSU includes a PSU fan, and the TMC is configured to set a given rotation speed of the PSU fan to be equal to or larger than a maximal value of the multiple rotation speeds.

In other embodiments, the controller is configured to control a rotation direction of the fan, the multiple measurements include two or more given measurements indicative of ambient temperatures of the electronic system, and the controller is configured to determine the rotation direction of the fan based on a minimal ambient temperature among the ambient temperatures.

In yet other embodiments, at least one of the cooling devices includes a pump configured to flow cooling fluid for cooling at least one of the multiple locations, at least a parameter among the multiple parameters includes a flow rate of the cooling fluid, and the controller is configured to calculate the ratio between the flow rate of the cooling fluid and a corresponding PWM parameter among the multiple PWM parameters.

There is additionally provided, in accordance with an embodiment of the present invention, a method including receiving multiple measurements of multiple temperatures measured in multiple locations of an electronic system, respectively. The multiple measurements are converted into multiple pulse width modulation (PWM) parameters. One or more PWM signals are calculated based on at least the multiple PWM parameters, and the multiple temperatures are controlled by applying the one or more PWM signals to one or more cooling devices.

The present invention will be more fully understood from the following detailed description of the embodiments thereof, taken together with the drawings in which:

### BRIEF DESCRIPTION OF THE DRAWINGS

FIG. 1 is a schematic, pictorial illustration of a switch system used in a communication network, in accordance with an embodiment of the present invention;

FIG. 2 is a block diagram that schematically illustrates monitoring and controlling the temperature of components in the switch system of FIG. 1, in accordance with an embodiment of the present invention; and

FIG. 3 is a flow chart that schematically illustrates a method for monitoring and controlling the temperature of components of the switch system of FIG. 1, in accordance with an embodiment of the present invention.

### DETAILED DESCRIPTION OF EMBODIMENTS

### Overview

Electronic systems, such as switch systems of communication networks (also referred to herein as network switches), typically generate heat while being operated. For example, each switch system may comprise several types of electronic devices, such as but not limited to an application-specific integrated circuits (ASIC), processors and/or controllers, and memory storage devices. During the operation of the switch system, the electronic devices generate heat, which may reduce the functionality of the system, and in severe cases, may burn out one or more components of the system. Various heat dissipation solutions have been developed for such systems, but each solution uses different hardware and software techniques, and a universal solution for thermal management is required to be implemented in one or more communication networks having different types of switch systems.

Embodiments of the present invention that are described hereinbelow provide techniques for improving the heat dissipation in electronic systems, such as in various types of switch systems used in communication networks.

In some embodiments, a switch system comprises multiple devices, such as but not limited to (i) one or more switches implemented in one or more ASICs, (ii) one or more data processing units (DPUs), (iii) a processor, (iv) electro-optical transceivers, (v) a power supply unit, (vi) cooling devices, such as fans and fluid pumps, and (vii) one or more drivers configured to drive signals to the cooling devices. The switch system further comprises temperature sensors positioned at predefined locations (also referred to herein as thermal zones) within the switch system. It is noted that at least some of the devices are positioned at the predefined locations, and at least some of the temperature sensors are embedded within the devices. For example, one or more of the temperature sensors are embedded within the ASIC. As such, the temperature sensors are configured to produce signals indicative of the temperature at the respective predefined locations.

In some embodiments, the switch system comprises an apparatus for controlling the temperatures at some or all of the predefined locations (e.g., thermal zone). The apparatus comprises an interface configured to receive the measurements of the temperatures from the respective temperature sensors. The apparatus further comprises a controller, e.g., implemented in the processor described above, or as a separate controller device. The controller is configured to convert the multiple measurements of the temperatures at each of the predefined locations into multiple pulse width modulation (PWM) parameters, each of which is associated with a respective predefined location.

It is noted that the PWM parameters are measured in percentage and may differ from one another. For example, first and second PWM parameters are associated with the ASIC and the processor located at different locations and having PWM parameters of about 70% and 50%, respectively, and the values of all other PWM parameters are less than about 50%.

In some embodiments, the controller is configured to calculate, based on the PWM parameters, one or more PWM signals. In one example, the controller may select, among all the PWM parameters, the maximal PWM parameter (e.g., 70%) for calculating the PWM signal. In another example, the controller may select two or more PWM parameters, for calculating two or more PWM signals, respectively.

In some embodiments, the one or more drivers are configured to drive the one or more PWM signals, calculated by the controller, to the one or more cooling devices, respectively.

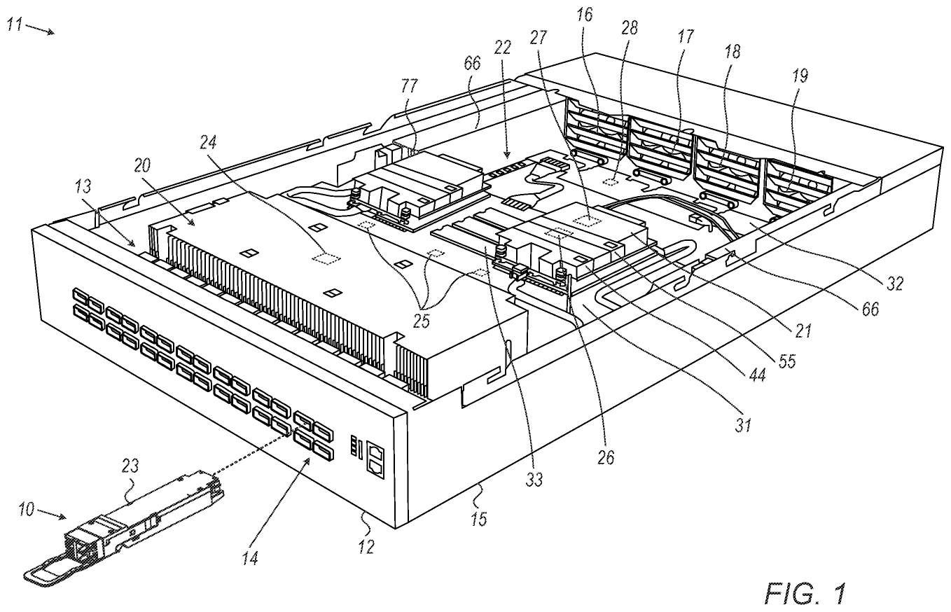

In some embodiments, in case of an error in one or more components of the switch system, e.g., temperature sensor(s) and/or cooling devices, the controller is configured to adjust at least one of the PWM signals in order to either compensate for the error or increase the level of cooling to obtain thermally safe operation of the switch system. Additional embodiments of the present disclosure are depicted in more detail in FIGS. 1-3 below.

The disclosed techniques improve the availability and performance of communication systems by optimizing the thermal performance of such systems. Moreover, the disclosed techniques provide a unified temperature control flow across all types of switch systems, regardless of the type of software and/or firmware that may be used for managing the thermal control of the respective types of switch systems.

### System Description

FIG. 1 is a schematic, pictorial illustration of an electronic system, in the present example, a switch system 11 used in a communication network, in accordance with an embodiment of the present invention. Switch system 11 is also referred to herein as system 11, for brevity.

In some embodiments, system 11 comprises a front panel 12 having sockets 14 connecting between electro-optical transceivers (EOTRs) 10, which is configured to be plugged into and unplugged from a connector 13. In the present example, connector 13 comprises a quad small form factor pluggable (QSFP) connector. In some embodiments, each EOTR 10 comprises a temperature sensor 23 configured to produce signals indicative of the temperature measured in EOTR 10, and when EOTR 10 is plugged in a given connector 13.

In some embodiments, system 11 comprises a housing 15 for packaging the components described below, and circuit boards (CBs) 31 and 32 having multiple devices and other components, which are mounted thereon and are described in detail below.

In some embodiments, system 11 comprises a network switch device, which is implemented in an application-specific integrated circuit (ASIC) 20 in the present example, and ASIC 20 is mounted on CB 31. It is noted that ASIC 20 generates heat while being operated. In some embodiments, system 11 comprises a temperature sensor 24, which is embedded in ASIC 20 (but could alternatively be coupled to ASIC 20). In some embodiments, sensor 24 may be implemented as multiple temperature sensors implemented at several respective locations across ASIC 20. These temperature sensors are configured to produce signals indicative of the temperature measured at the one or more locations across ASIC 20.

In some embodiments, system 11 comprises a processor 44, e.g., a suitable type of a central processing unit (CPU) or any other suitable type of processing unit, and a temperature sensor 26, which is coupled to or embedded within processor 44. Sensor 26 is configured to produce signals indicative of the temperature measured at one or more positions within processor 44.

In some embodiments, system 11 comprises additional components, such as (i) a power regulator (DCDC) mounted on the opposite side of CB 31 and therefore is not shown, DCDC is configured to convert a first direct current (DC) to a second DC, (ii) temperature sensors 25 configured to produce signals indicative of the temperature at multiple positions of the DCDC, (iii) an interface 55, configured to exchange signals between processor 44 and other entities of system 11, as will be described in detail below, (iv) a memory device, in the present example, a Double Data Rate Synchronous Dynamic Random-Access Memory (DDR SDRAM), referred to herein as a DDR 21 for brevity, (v) a temperature sensor 27, which is coupled to or embedded within DDR 21, and is configured to produce signals indicative of the temperature measured at one or more positions across DDR 21.

In some embodiments, system 11 comprises one or more heat sinks and thermal interface material (TIM) disposed over at least some of the heat generating devices (e.g., ASIC 20, processor 44, and DDR 21) for increasing the dissipation rate of the heat generated by these devices.

In some embodiments, system 11 comprises multiple cooling device, in the present example fans 16, 17, 18 and 19 configured to rotate at controllable rotation speeds, e.g., measured in revolutions per minute (RPM), so as to blow air (into system 11 or out of system 11) for cooling thermal zones of system 11. The operation of fans 16-19 is controlled as will be described in detail below.

In the context of the present disclosure and in the claims, the term “thermal zone” and grammatical variations thereof refer to location(s) within system 11, whose temperatures are monitored using the signals received from the temperature sensors described above.

In some embodiments, system 11 comprises one or more power supply units (PSUs) 66, which is configured to supply power to at least some components (e.g., ASIC 20, processor 44, DDR 21, and connectors 13), and typically to all the power-consuming components of system 11. In some embodiments, system 11 further comprises one or more PSU cooling devices, in the present example, PSU fans 77 (e.g., each PSU 66 has at least one PSU fan 77). PSU fans 77 are configured to rotate at controllable rotation speeds (e.g., measured in RPMs) for cooling PSU 66. Moreover, system 11 comprises one or more temperature sensors 28 (also referred to herein as ambient temperature sensors 28) configured to produce signals indicative of the temperature measured at one or more positions across system 11. In the present example, a single temperature sensor 28 is mounted on CB 32 for monitoring the ambient temperature of system 11, but in other embodiments, system 11 may comprise any suitable number of temperature sensors 28 mounted at any suitable positions within system 11.

In some embodiments, system 11 comprises one or more drivers 33 configured to drive signals to several cooling devices of system 11. In the present example, drivers 33 are implemented in Field Programmable Gate Arrays (FPGAs), but in other embodiments, drivers 33 may be implemented in any other suitable type of device. Drivers 33 are configured to drive signals to fans 16-19 for blowing the air, and thereby, for controlling the temperature of selected components of system 11 (e.g., connectors 13, ASIC 20, processor 44, interface 55, DDR 21, drivers 33, and the power regulator DCDC).

In some embodiments, system 11 comprises thermal management circuitry (TMC) 22, comprising: (i) a controller implemented in processor 44, and (ii) one or more drivers 33. In some embodiments, interface 55 is configured to receive from the temperature sensors of system 11, signals indicative of measurements of temperatures in multiple thermal zones of system 11.

As described above, the term “thermal zones” refers to locations within system 11, whose temperatures are monitored using the signals received from the temperature sensors described above.

In the present example, interface 55 receives signals from temperature sensors 23, 24, 25, 26, 27 and 28, which are indicative of the measurements of temperatures in respective thermal zones of system 11. The thermal zones typically surround one or more temperature sensors. For example, ASIC 20 constitutes a first thermal zone surrounding temperature sensor 24, and the power regulator constitutes a second thermal zone surrounding temperature sensors 25.

In some embodiments, the controller is configured to convert the measurements received from the temperature sensors into pulse width modulation (PWM) parameters, which are indicative of the required rotation speeds (e.g., RPMs) of the fans of system 11. It is noted that based on the temperature measurements, each thermal zone receives a PWM parameter. As such, TMC 22 serves as a thermal entity, which is defined as an entity that monitors the thermal zones (based on the temperature measurements), and controls the cooling devices (e.g., fans 16-19) of system 11, as described herein.

In some embodiments, based on the multiple PWM parameters, the controller is configured to calculate one or more PWM signals. For example, the controller is configured to convert: (i) a relatively low temperature (e.g., about 40° C.) measured in ASIC 20 by sensor 24, to a relatively low PWM parameter (e.g., PWM of about 30%), (ii) a relatively high temperature (e.g., about 70° C.) measured in processor 44 by sensor 26, to a relatively high PWM parameter (e.g., PWM of about 75%), and (iii) temperatures smaller than about 60° C. measured by the other temperature sensors described above, to PWM parameters smaller than about 75%.

In some embodiments, the controller is configured to: (i) select the maximal PWM parameter among all the calculated PWM parameters (in the present example about 75%), and (ii) calculate, based on the maximal PWM parameter (of 75%), a unified PWM signal to all fans 16-19.

In some embodiments, the one or more drivers 33 are configured to apply the unified PWM signal to all the cooling devices of system 11, in the present example, to fans 16-19. It is noted that the relatively high PWM parameter of 75%, is required only for controlling the temperature in processor 44, but this level of PWM parameter is applied to all fans 16-19 in order to mitigate the excess heat formed in the hottest thermal zone of system 11.

In alternative embodiments, the controller is configured to calculate two or more PWM signals based on the converted PWM parameters. For example, fans 17 and 18 are facing processor 44, and therefore, driver 33 may apply: (i) a first PWM signal to fans 17 and 18 based on the 75% PWM parameter, and (ii) a second PWM signal to fans 16 and 19 based on a PWM parameter having a smaller value (e.g., about 65%).

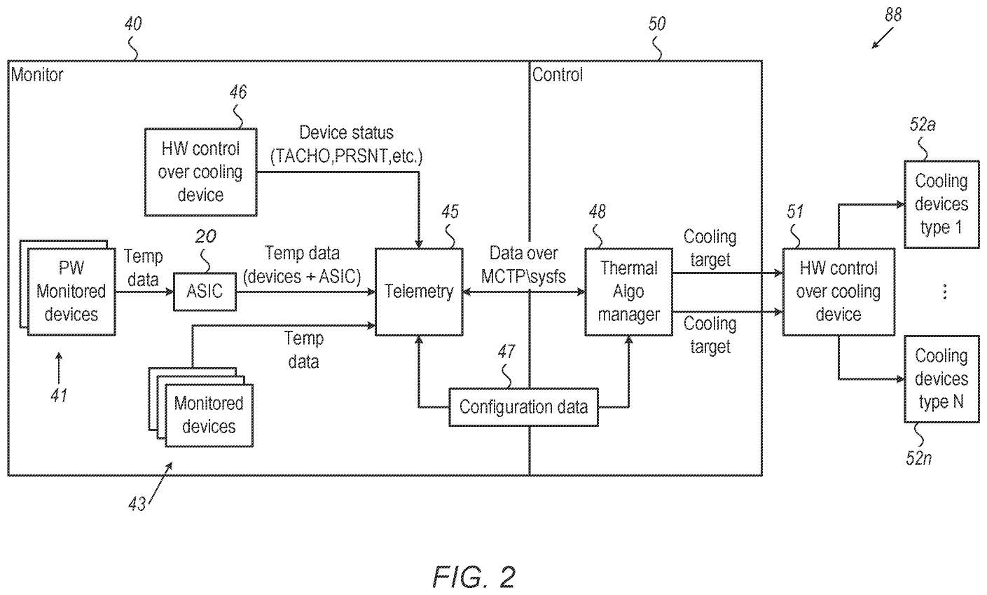

In some embodiments, the controller is configured to calculate a ratio between the PWM parameters, and one or more parameters of each of the fans 16-19 of system 11. In the present example, all fans 16-19 are similar, and the ratio could be between the PWM parameter and the rotation rate of the respective fan (measured in RPM). A technique for calculating the ratio is described in detail in FIG. 2 below.

In some embodiments, at least two fans among fans 16-19 (e.g., fans 16 and 17) may differ from one another. As such, the ratio between the PWM parameter and the rotation speed may differ between fans 16 and 17, and is monitored in each fan among fans 16-19. It is noted that a deviation from the ratio between the PWM and the RPM is indicative of an error in the respective fan.

In some embodiments, in case, in a given fan, the RPM does not fit the PWM, the controller is configured to (i) notify the user of a failure in the given fan, and if needed, (ii) adjust the PWM applied by driver 33 to the other fans in order to compensate for the failure of the given fan.

In some embodiments, the process described above is iterative, so that in response to a change in the measured temperature, the controller adjusts the respective PWM parameter, and compares: (i) the PWM parameters calculated in all thermal zones, and (ii) the calculated maximal PWM parameter with the PWM parameter applied by the present PWM signal. In case the calculated maximal PWM parameter is larger than the PWM parameter applied by the present PWM signal, the controller is configured to adjust the PWM signal by applying the calculated maximal PWM parameter to the cooling device (e.g., fans 16-19).

For example, in case the temperature in ASIC 20 (measured by sensor 24) increases, e.g., to about 80° C., the controller is configured to adjust the PWM parameter of the thermal zone having ASIC 20, to about 80%. At the same time, the temperature in processor 44 remains at approximately 70° C. In this example, the controller adjusts the maximal PWM parameter to 80%, and PWM parameter calculates a revised PWM signal based on the maximal to 80%. And driver 33 applies the revised PWM signal to fans 16-19.

In some embodiments, in response to applying the revised PWM signal, the rotation speed (e.g., RPM) of fans 16-19 is altered, so as to control (e.g., reduce) the temperature of the thermal zone having ASIC 20 and the other thermal zones. For example, (i) the rotation speed of one or more of the fans may be increased in order to reduce the temperature of the one or more respective thermal zone(s), or alternatively, (ii) the rotation speed of one or more of the fans may be decreased, e.g., in order to save power as long as the temperature of the one or more respective thermal zone(s) is within the specified range of temperatures. It is noted that the PWM adjustment is carried out as part of the optimization of the temperature and the power consumption of system 11.

Moreover, in response to receiving from sensor 24 a signal indicative of the temperature being reduced, e.g., to about 50° C., the controller re-adjusts the PWM parameter of the thermal zone having ASIC 20, identifies the maximal PWM parameter among all the thermal zones, compares between the maximal PWM parameter and the 80% PWM parameter, and if applicable, the controller produces another revision of PWM signal, which the driver applies to fans 16-19.

It is note that in the present example, all the cooling devices comprise fans, but in other embodiments, at least one of the cooling devices of system 11 may comprise a pump (not shown), which is configured to flow cooling fluid for cooling at least one of the thermal zones (i.e., locations) in system 11. In such embodiments, the parameter may comprise the flow rate of the cooling fluid, and the controller is configured to calculate the ratio between the flow rates and the corresponding PWM parameters intended to be driven by driver 33 into the pump.

In some embodiments, PSU 66, and PSU fan 77 may be controlled using a separate controller referred to herein as a given controller, and may receive PWM signals from another driver (not shown). It is noted that in order to prevent or at least reduce turbulence within system 11, the flow rate of the air moved by the rotation of PSU fan 77, must be equal to or higher than the maximal flow rate of the air moved by each of fans 16-19. As such, the rotation speed of PSU fan 77 is typically equal to or higher than the rotation speed of each of fans 16-19.

In some embodiments, in response to identifying that the PWM parameter of PSU fan 77 is smaller than that of the maximal PWM parameter applied to fans 16-19 (i.e., smaller than the PWM parameter required by system 11), the controller of system 11 (which is implemented in processor 44 as described above) is configured to override the given controller. As such, the controller of system 11 is configured to calculate a revised PWM signal intended to be applied to PSU fan 77. The revised PWM signal is similar to or larger than the maximal PWM parameter calculated for system 11, so as to prevent turbulence in the air flowing within system 11.

The implementations of the techniques depicted above are described in more detail in FIG. 2 below.

FIG. 2 is a block diagram 88 that schematically illustrates monitoring and controlling the temperature of components in switch system 11, in accordance with an embodiment of the present invention.

In some embodiments, block diagram 88 comprises: (i) a group of monitoring blocks, referred to herein as a monitor 40, (ii) a group of controlling blocks, referred to herein as a control 50, and (iii) the application of the PWM signals (e.g., using driver(s) 33) to the cooling devices (e.g., fans 16-19).

In some embodiments, monitor 40 comprises a telemetry unit 45, configured to receive: (i) the temperature data from blocks 41 and 43, and from ASIC 20, and (ii) the status of the cooling devices (e.g., fans 16-19) from a block 46, as will be described in more detail below. In the present example, telemetry unit 45 may be implemented in interface 55 and/or in processor 44, and block 46 may be implemented in the controller, which is implemented in processor 44.

In some embodiments, the data received from blocks 41 and 43, and ASIC 20 comprises the temperature data of (a) EOTRs 10, (b) ASIC 20, (c) the power regulator (DCDC), (d) processor 44 and interface 55, (e) DDR 21, and (f) CB 32, which is received from sensors 23, 24, 25, 26, 27 and 28, respectively, as described in detail in FIG. 1 above. In the present example, ASIC 20 receives from block 41 the temperature data from one or more of sensors 23, 25-28, adds the temperature data received from sensor 24, and sends the data to telemetry unit 45. Additionally, or alternatively, telemetry unit 45 receives the temperature data of one or more of sensors 23, 25-28 directly from block 43.

In some embodiments, the controller is configured to apply an algorithm for optimizing the impact of the power, noise, and other parameters of the cooling devices (e.g., fan and/or fluid pump) as a function of the temperature of the critical devices of system 11 (e.g., ASIC 20 and processor 44). As such, in a configuration data block 47, the controller is configured to determine, inter alia, a list of components (e.g., devices), and based on the signals received from the temperature sensors (indicative of the temperature reads in the respective components), the controller is configured to output a specific behavior of the cooling devices for each state of the monitored devices and cooling devices.

In some embodiments, for each device of system 11 that has a heat-sink for dissipating the heat generated by the respective device, it is expected that the cooling impact will be slower than the change in the speed of the airflow. Therefore, the it is assumed that ASIC 20 is configured to provide its own monitored temperature to the controller using a specific frequency bandwidth, in the present example about 0.1 Hz or any other suitable frequency.

Reference is now made to control 50. In some embodiments, control 50 comprises a thermal algorithm manager block 48, which is implemented in the controller in the present example, and is configured to receive, from telemetry unit 45, the data of temperature and the status of fans 16-19 as described above. It is noted that the data received from telemetry unit 45 is subject to the parameters received from configuration data block 47. In the present example, the data from telemetry unit 45 is received over a Management Component Transport Protocol (MCTP), or using any other suitable type of protocol.

In some embodiments, based on the data received from telemetry unit 45, thermal algorithm manager block 48 is configured to: (i) convert the temperature measurement into PWM parameters, and (ii) generate, based on the PWM parameters and additional input (such as one or more errors in components of system 11, described below) one or more PWM signals that constitute cooling targets for each of the thermal zones described above.

In some embodiments, the controller is configured to select the maximum PWM parameter among the PWM parameters described above, and to apply the maximum PWM parameter to a common PWM signal intended to be applied to all fans 16-19, as described in detail in FIG. 1 above. Alternatively, the controller is configured to calculate multiple PWM signals intended to be applied to multiple types of cooling devices (e.g., fans or pumps), respectively.

In some embodiments, in a block 51, which is implemented in drivers 33, the one or more drivers 33 are configured to: (i) receive the PWM signal(s) from the controller, and (ii) drive the PWM signal(s) to blocks 52 indicative of the cooling devices of system 11. In the general example, system 11 comprises an n number of types of blocks 52a-52n (i.e., different type of cooling devices), and one or more drivers 33 are configured to drive either: (i) the PWM signal having the maximum PWM parameter to two or more (e.g., all of) blocks 52a-52n, or (ii) different PWM signals based on different PWM parameters, as described above. In the present example, block 52a comprises fans 16-19, and the PWM signal being applied to fans 16-19 is based on the maximal PWM parameter among the calculated PWM parameters. The calculation of the PWM parameters is described in detail below.

In some embodiments, while the management of monitor 40 and control 50, which is implemented in software and/or firmware is not available (e.g., during software boot or software hang) the hardware (e.g., drivers 33) shall control the cooling device (e.g., fans) assuming the worst-case scenario. As such, drivers 33 drive fans to the maximal level of cooling.

In some embodiments, during the initialization of the cooling apparatus, the controller is configured to run one cycle of the algorithm (described below), and to carry out the PWM parameters setting after the initialization stage. It is noted that in order to prevent a state of undesired throttling or an undefined value prior to getting the temperature and rotation speed data from the system, the controller takes control over the cooling devices (e.g., fans 16-19) only after the initialization stage.

In some embodiments, the controller is configured to receive signals indicative of the rotation speed of each fan, and based on the PWM parameters and the rotation speed, the controller is configured to determine the properties of each fan. It is note that at least one of fans 16-19 starts to operate from a predefined PWM, also referred to herein as a minimum PWM parameter. Moreover, each of fans 16-19 has a minimum level of rotation speed (e.g., measured in RPM), as such, the calculation of the ratio between the PWM and RPM assumes that the RPM below the minimum level of PWM is equal to the minimum level of the RPM. Furthermore, the calculation of the linear line slope (of the PWM vs RPM) assumes that the average slope is only calculated for RPMs obtained at levels of the PWM parameters that are larger than the minimum level of PWM.

In some embodiments, the controller is configured to calculate PWM for each thermal zone (e.g., component) of system 11, using the following parameters:
Tₛₑₙₛₒᵣ denotes the temperature read from the temperature sensor of each component (e.g., ASIC 20, processor 44, and the other components described in FIG. 1 above),

Tₘᵢₙ denotes the minimum temperature of each of the components,
Tₘₐₓ denotes the maximum temperature allowed for each of the components,
PWMₘᵢₙ denotes the minimum percentage (%) of PWM of each of the components, and
PWMₘₐₓ denotes the maximum percentage (%) of PWM of each of the components.

In such embodiments, the controller is configured to calculate the PWM (in %) for each component, using the following conditional flow:
(a) if Tₛₑₙₛₒᵣ is smaller than T_{Min}, then PWM equals PWMₘᵢₙ,
(b) if Tₛₑₙₛₒᵣ is larger than T_{Max}, then PWM equals PWMₘₐₓ, and
(c) if Tₛₑₙₛₒᵣ is between T_{Min} and T_{Max}, the value of the PWM parameter is calculated using an equation (i):

$$P W M = P W {M}_{Min} + \frac{{T}_{sensor} - {T}_{Min}}{{T}_{Max} - {T}_{Min}} * ( P W {M}_{Max} - P W {M}_{Min} ) \qquad ( i )$$

It is noted that the output of equation (i) provides a continuous value of the PWM parameter that takes into consideration the temperature change, and the controller can react as a proportional-integral-derivative (PID) controller while retaining the values of PWMₘₐₓ for T_{Max} and PWMₘᵢₙ for Tₘᵢₙ.

In some embodiments, the PWM parameter is represented using a 255-bit register, as such the representation of calculated PWM in the 255-bit register, is provided by an equation (ii):

$${PWM}_{reg} = [ \frac{255 * P W M + 50}{100} ] \qquad ( ii )$$

Wherein PWM_{reg} denotes the calculated PWM in the 255-bit register.

In some embodiments, the setting of the PWM parameter takes into consideration errors that may occur in various components of system. The errors and the PWM setting (with and without the errors) will be described in detail below.

In some embodiments, block 46 receives from fan tachometers (not shown) of fans 16-19, signals indicative of the rotation speed (e.g., RPM) of fans 16-19 responsively to PWM parameters driven to fans 16-19 by one or more drivers 33. It is noted that each of fans 16-19 can reach predefined levels of a minimum rotation speed, and a maximum rotation speed, referred to here as RPMmin and RPMmax, respectively.

In some embodiments, based on the applied PWM parameters and the corresponding RPM data received from the tachometers, the controller is configured to calculate an average value of a linear slope for each fan among fans 16-19. Moreover, the controller is configured to calculate, for each of fans 16-19, a fan PWM tolerance using an equation (iii):

$$y = m * x + b \qquad ( iii )$$

Wherein,
y denotes the RPM measure by the fan tachometer,
m denotes the average slope between the PWM and RPM,
x denotes the PWM applied by driver 33, and
b denotes a constant whose calculation is described below.

In some embodiments, the controller is configured to calculate the average slope of the ratio between the PWM and the RPM using the following conditional flow:

For each level of PWM, denotes PWM[i],

$$If PWM [ i ] < {PWM}_{min}$$

$$isValid [ i ] = 0$$

Wherein isValid[i] denoted the validity factor of PWM[i].

In other words, if the value of PWM[i] is smaller than the value of PWMₘᵢₙ, the respective PWM[i] will not be used for calculating the slope of the ratio between the PWM and the RPM. As such, a validity factor (shown below) receives a value of zero.

In some embodiment, if the value of PWM[i] is larger than the value of PWMₘᵢₙ, the respective PWM[i] will be used for calculating the slope of the ratio between the PWM and the RPM (i.e., the validity factor isValid[i]=1).

In some embodiments, the average slope is calculated by calculating the slope at each instance [i] multiplied by the validity factor that receives a value of 1 (when valid) or 0 (when invalid). As such, the average slope is calculated using an equation (iv):

$$AverageSlope = \frac{SUM ( {Slope}_{a} )}{SUM ( isValid )} \qquad ( iv )$$

Where Slopeₐ[i] denotes the slope at each instance [i]

In some embodiments, the controller is configured to calculate the constant “b” using an equation (v):

$$b = R P {M}_{max} - AverageSlope * {PWM}_{max} \qquad ( v )$$

In such embodiments, the controller is configured to calculate the rotation speed (e.g., RPM) for each fan among fans 16-19, using the following conditional flow:
(a) if the value of the PWM parameter is smaller than the minimum value of PWM (PWMₘᵢₙ), the level of RPM is set to the minimum RPM level (RMMₘᵢₙ), otherwise
(b) the controller is configured to calculate the RPM using an equation (vi):

$$RPM = AverageSlope * PWM + b \qquad ( iv )$$

An example of values of the PWM parameter for a device, the measured rotation speed, calculated slope, validity factor, and calculated rotation speed, are shown in a table (A) shown below:

TABLE A
An example of PWM parameters, measured RPM, calculated
slope, validity factor, and calculated RPM.

| | Measured | | | Actual Slope | Calculated |
|---|---|---|---|---|---|
| | rotation | | | based on | rotation |
| PWM | speed [RPM] | Slope | isValid | validity factor | speed [RPM] |
| 0 | 0 | 300 | 0 | 0 | 3000 |
| 10 | 3000 | 0 | 0 | 0 | 3000 |
| 20 | 3000 | 160 | 1 | 160 | 3000 |
| 30 | 4600 | 140 | 1 | 140 | 4500 |
| 40 | 6000 | 150 | 1 | 150 | 6000 |
| 50 | 7500 | 160 | 1 | 160 | 7500 |
| 60 | 9100 | 140 | 1 | 140 | 9000 |
| 70 | 10500 | 150 | 1 | 150 | 10500 |
| 80 | 12000 | 170 | 1 | 170 | 12000 |
| 90 | 13700 | 130 | 1 | 130 | 13500 |
| 100 | 15000 | | | | 15000 |
| RPM | 3000 | | | | |
| min | | | | | |
| PWM | 20 | | | | |
| min | | | | | |
| RPM | 15000 | | | | |
| max | | | | | |
| Avg | 150 | | | | |
| slope | | | | | |
| b | 0 | | | | |

### Error Detection and Impact on Thermal Management

Various types of errors and failures could occur during the operation of switch system 11. For example, errors in one or more of the: PSU fans 77, fans 16-19 and/or the aforementioned fluid pumps (in case of fluid-based cooling), and in the temperature readings, which are carried out by sensors 23-28.

In some embodiments, the controller is configured to dynamically update the data and parameters of table (A) above, and to hold thermal management protocols in response to detection of at least the errors (and optionally other scenarios) described in detail below.

The errors in the PSU fans 77 may include (i) absence of one or more PSU fans 77 (e.g., by improper replacement of one or more PSU fans 77 during maintenance), and (ii) a failure to operate one or more of PSU fans 77.

The errors in one or more of fans 16-19 may include (i) absence of one or more of fans 16-19 (e.g., by improper replacement of one or more of these fans during maintenance), (ii) installation of one or more of the fans in an opposite direction, resulting in flowing air in a direction opposite to the required direction, and (iii) error in the calculated ratio between the PWM and the rotation speed of fans 16-19.

It is noted that system 11 may allow a single direction of the air flow, or two directions of the air flow. Moreover, each of the fans has an indication of the direction of airflow, e.g., pushing the air into system 11, or drawing the air out of system 11.

In some embodiments, the indication of the direction of each fan among fans 16-19 and 77 is stored in system 11, for example in registers in processor 44. In other words, the intended direction of the airflow (e.g., pushing or drawing the air) is stored.

In some embodiments, in case of a single direction of air flow, the controller implemented in processor 44 is configured to detect the actual direction of the air flow. In one implementation, the actual air flow direction may be detected by mounting an additional ambient temperature sensor 28, e.g., between panel 12 and ASIC 20 (or at any other suitable location in system 11, and comparing the temperature readings received from both sensors 28. As such, the lower temperature reading is indicative of the upstream direction of the air flow. Additionally, or alternatively, the direction of air flow may be obtained using a suitable airflow sensor.

In some embodiments, in both cases of one-direction or two-direction airflows, the controller compares for each of the fans whether the actual and the intended directions of the airflow are similar. In case of a discrepancy between the actual direction and the intended direction, the controller is configured to identify an error in the actual direction of the airflow. In such embodiments, if the operator of system 11 allows, the controller is configured to initiate a corrective action in the respective fan. Alternatively, the controller is configured to adjust the calculation of the PWM based on the error identified in the actual direction of the airflow.

In some embodiments, the controller is configured to: (i) define a frequency of the temperature measurement for each of the temperature sensors located at each of the thermal zones, and (ii) detect a failure in the temperature reading, e.g., by not receiving one or more scheduled temperature reads in accordance with the predefined frequency. Moreover, extreme temperature reading that are way off the predefined control limits of the heat management in system 11 (e.g., stored in processor 44), may also be indicative of a failure in the temperature reading (but in case the temperatures slightly exceed the control limits, may also be indicative of real overheating in the respective thermal zone). In some embodiments, while retrying to receive new temperature readings, the controller is configured to apply the techniques described in FIGS. 1 and 2 based on the one or more latest valid temperature readings received from the respective temperature sensor.

In some embodiments, the controller is configured to hold one or more criteria for defining a failure in the temperature reading. For example, a criterion comprises three sequential failures of the temperature readings from the same temperature sensor.

In some embodiments, all the errors described above, and other errors related to the thermal management of system 11 are logged and may be used by the controller for adjusting parameters related to the PWM, rotation speed of the fans, and other parameters shown in table (A) above.

In some cases, an event that the controller is not familiar with, or does not hold a suitable thermal management protocol for it, may occur. In some embodiments, in response to identifying one or more of the above events, the controller is configured to set all the fans of system 11 (e.g., fans 16-19) to their maximal rotation speed. Moreover, in response to an error in the temperature reading from ambient sensor 28, the controller is configured to set a predefined maximal ambient temperature, and to calculate the PWM and the other parameters shown in table (A) above, based on the predefined maximal ambient temperature.

In some cases, additional temperature sensors may be coupled to EOTRs 10. In some cases, the signals received from such sensors may be indicative of: (i) errors in temperature readings, and/or (ii) overheating of an AOC. In some embodiments, while conducting the thermal management of system 11, the controller may not use the data received from these sensors for adjusting parameters that are related to the thermal management of system 11. It is noted that such AOCs are easy to replace, and local overheating of a specific AOC may occur due to a local failure in the AOC, which is not related to the operation of system 11.

In alternative embodiments, instead of or in addition to the controller, the thermal management in system 11 may be carried out using any other suitable processing device and software and/or firmware. For example, at least some of the thermal management techniques described above may be carried out using firmware running on ASIC 20, or using any other entity comprising suitable device and software and/or firmware.

In some embodiments, the controller is configured to adjust the PWM, e.g., responsively to changes in the temperature reads, as described above. Moreover, the controller is configured to hold one or more thresholds indicative of the fastest allowed lowering rate of the PWM, in order to avoid oscillations in the fans of system 11, which are not good for the stability of the fans, as well as other undesired phenomena such as the noise generated by the fans.

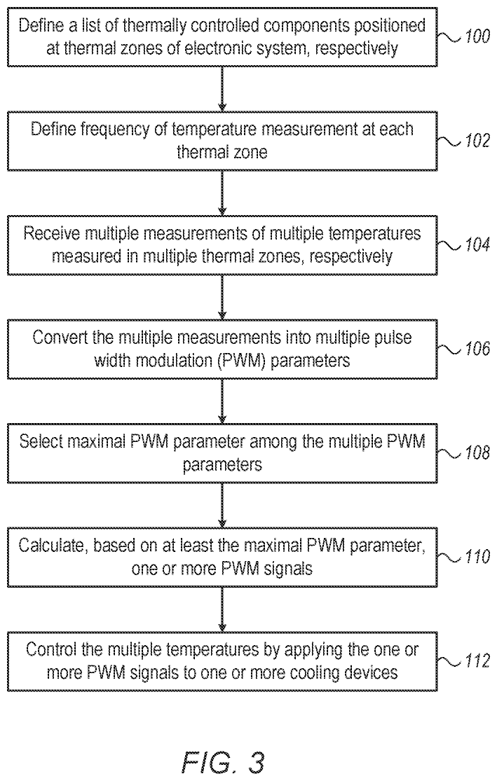

FIG. 3 is a flow chart that schematically illustrates a method for monitoring and controlling the temperature of components of switch system 11, in accordance with an embodiment of the present invention.

The method begins at a component definition step 100 with defining a list of multiple thermally controlled components (e.g., ASIC 20, processor 44, and other components described in FIG. 1 above) that are positioned at multiple locations, also referred to herein as thermal zones of electronic system 11, respectively. It is noted that the definition of thermally controlled components may be carried out by a designer and/or a user of system 11, but the list can also be defined by the controller implemented in processor 44, or by any other suitable component of system 11.

At a polling time definition step 102, the controller defines a frequency of the temperature measurement at each thermal zone, as described in detail in FIGS. 1 and 2 above.

At a measurement receiving step 104, interface 55 receives from one or more of sensors 23-28 located at the thermal zones, multiple measurements of multiple respective temperatures, as described in detail in FIGS. 1 and 2 above. It is noted that the temperatures are measured based on the predefined list of thermally controlled components and measurement frequencies defined in steps 100 and 102 above.

At a conversion step 106, the controller checks whether one or more errors occurred in one or more of: (i) temperature readings by the temperature sensors, and (ii) one or more of cooling devices (e.g., fans 16-19, and PSU fan 77). In some embodiments, the controller converts the multiple measurements into multiple PWM parameters. It is noted that the controller is configured to adjust the PWM parameters in response to detecting the occurrence of any of the aforementioned errors, as described in detail in FIGS. 1 and 2 above.

At a PWM parameter selection step 108, the controller selects a maximal PWM parameter among the multiple PWM parameters of step 102 above, as described in detail in FIGS. 1 and 2 above. In alternative embodiments, the controller may select PWM parameters in addition to or instead of maximal PWM parameter.

At a signal calculation step 110, the controller calculates based on at least the maximal PWM parameter, one or more PWM signals. In some embodiments, the controller is configured to calculate the PWM signals based on additional parameters, such as different types of cooling devices (e.g., different type of air fans, and pumps configured to flow cooling fluid for cooling the thermal zones). In alternative embodiments, the controller is configured to set the PWM parameters in step 106 based on the temperature reads, and subsequently (e.g., in step 110), the controller is configured to adjust the PWM signal in response to the errors occurred in at least one of the temperature sensors and/or the cooling devices (e.g., any of the aforementioned fans 16-19) of switch system 11.

At a temperature controlling step 112 that concludes the method, TMC 22 is configured to control the multiple temperatures at the multiple temperature zones by using one or more of drivers 33 to apply the one or more calculated PWM signals to the one or more cooling devices. In one implementation, the controller calculates the PWM signal based on the maximal PWM parameter, and driver 33 applies the calculated PWM signal to fans 16-19, as described in detail in FIGS. 1 and 2 above.

The method of FIG. 3 is simplified for the sake of conceptual clarity, and additional sub-steps, such as but not limited to calculating the correlation between the PWM parameters and the rotation speeds of the respective fans, are described in detail in FIGS. 1 and 2 above. Moreover, the method of FIG. 3 is based on the particular configuration of switch system 11 which is shown by way of example, in order to illustrate certain problems that are addressed by embodiments of the present disclosure and to demonstrate the application of these embodiments in enhancing the performance of such a switch system. Embodiments of the present disclosure and variations thereof, however, are by no means limited to this specific sort of example switch system, and the principles described herein may similarly be applied to other sorts of electronic system having any suitable requirements of thermal management.

It will be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An apparatus, comprising:
an interface, to receive multiple measurements of multiple temperatures measured in multiple locations of an electronic system, respectively; and
thermal management circuitry (TMC), to:
convert the multiple measurements into multiple pulse width modulation (PWM) parameters;
calculate, based on at least the multiple PWM parameters, one or more PWM signals; and
control the multiple temperatures by applying the one or more PWM signals to one or more cooling devices.

2. The apparatus according to claim 1, wherein the TMC is to: (i) select a maximal PWM parameter among the multiple PWM parameters, and (ii) apply the maximal PWM parameter to all of the cooling devices.

3. The apparatus according to claim 1, wherein the TMC is to select a list of two or more components positioned at two or more of the locations, and comprising two or more temperature sensors coupled to the components, respectively, to perform the measurements of the temperatures in the components on the list, respectively.

4. The apparatus according to claim 3, wherein the interface is to receive an error signal indicative of an error in at least one of: (i) one or more of the cooling devices, and (ii) one or more of the temperature sensors, and wherein the TMC is to adjust at least one of the PWM signals responsively to the error.

5. The apparatus according to claim 3, wherein the multiple temperature sensors comprise first and second temperature sensors to perform first and second measurements, respectively, among the multiple measurements, and wherein the TMC comprises a controller, which is to define: (i) for the first temperature sensor, a first frequency of the first measurements, and (ii) for the second temperature sensor, a second frequency of the second measurements, different from the first frequency.

6. The apparatus according to claim 1, wherein the TMC comprises a controller, which is to calculate a ratio between the multiple PWM parameters and multiple parameters of the one or more cooling devices.

7. The apparatus according to claim 6, wherein at least one of the cooling devices comprises a fan, wherein at least a parameter among the multiple parameters comprises a rotation speed of the fan, and wherein the controller is to calculate the ratio between the rotation speed of the fan and a corresponding PWM parameter among the multiple PWM parameters.

8. The apparatus according to claim 7, and comprising (i) multiple fans controlled to operate at multiple rotation speeds, respectively, (ii) multiple components located in at least some of the multiple locations, and (iii) a power supply unit (PSU) to supply power to at least some of the multiple components, wherein the PSU comprises a PSU fan, and wherein the TMC is to set a given rotation speed of the PSU fan to be equal to or larger than a maximal value of the multiple rotation speeds.

9. The apparatus according to claim 7, wherein the controller is to control a rotation direction of the fan, wherein the multiple measurements comprise two or more given measurements indicative of ambient temperatures of the electronic system, and wherein the controller is to determine the rotation direction of the fan based on a minimal ambient temperature among the ambient temperatures.

10. The apparatus according to claim 6, wherein at least one of the cooling devices comprises a pump to flow cooling fluid for cooling at least one of the multiple locations, wherein at least a parameter among the multiple parameters comprises a flow rate of the cooling fluid, and wherein the controller is to calculate the ratio between the flow rate of the cooling fluid and a corresponding PWM parameter among the multiple PWM parameters.

11. A method, comprising:
receiving multiple measurements of multiple temperatures measured in multiple locations of an electronic system, respectively;
converting the multiple measurements into multiple pulse width modulation (PWM) parameters;
calculating, based on at least the multiple PWM parameters, one or more PWM signals; and
controlling the multiple temperatures by applying the one or more PWM signals to one or more cooling devices.

12. The method according to claim 11, wherein calculating the one or more PWM signals comprises selecting a maximal PWM parameter among the multiple PWM parameters, and wherein applying the one or more PWM signals comprises applying the maximal PWM parameter to all of the cooling devices.

13. The method according to claim 11, and comprising selecting a list of two or more components positioned at two or more of the locations, and receiving from two or more temperature sensors coupled to the components, respectively, measurements of the temperatures in the components on the list, respectively.

14. The method according to claim 13, and comprising receiving an error signal indicative of an error in at least one of: (i) one or more of the cooling devices, and (ii) one or more of the temperature sensors, and adjusting at least one of the PWM signals responsively to the error.

15. The method according to claim 13, wherein receiving the multiple measurement comprises receiving first and second measurements from first and second temperature sensors among the two or more temperature sensors, respectively, and comprising defining: (i) for the first temperature sensor, a first frequency of the first measurements, and (ii) for the second temperature sensor, a second frequency of the second measurements, different from the first frequency.

16. The method according to claim 11, wherein calculating the one or more PWM signals comprises calculating a ratio between the multiple PWM parameters and multiple parameters of the one or more cooling devices.

17. The method according to claim 16, wherein at least one of the cooling devices comprises a fan, wherein at least a parameter among the multiple parameters comprises a rotation speed of the fan, and wherein calculating the ratio comprises calculating the ratio between the rotation speed of the fan and a corresponding PWM parameter among the multiple PWM parameters.

18. The method according to claim 17, and comprising (i) multiple fans controlled to operate at multiple rotation speeds, respectively, (ii) multiple components located in at least some of the multiple locations, and (iii) a power supply unit (PSU) to supply power to at least some of the multiple components, wherein the PSU comprises a PSU fan, and wherein controlling the multiple temperatures comprises setting a given rotation speed of the PSU fan to be equal to or larger than a maximal value of the multiple rotation speeds.

19. The method according to claim 17, wherein controlling the multiple temperatures comprises controlling a rotation direction of the fan, wherein receiving the multiple measurements comprises receiving two or more given measurements indicative of ambient temperatures of the electronic system, and wherein controlling the rotation direction comprises determining the rotation direction of the fan based on a minimal ambient temperature among the ambient temperatures.

20. The method according to claim 16, wherein at least one of the cooling devices comprises a pump to flow cooling fluid for cooling at least one of the multiple locations, wherein at least a parameter among the multiple parameters comprises a flow rate of the cooling fluid, and wherein calculating the ratio comprises calculating the ratio between the flow rate of the cooling fluid and a corresponding PWM parameter among the multiple PWM parameters.

21. The method according to claim 11, wherein calculating the one or more PWM signals comprises selecting a PWM parameter among the multiple PWM parameters that meets a predetermined condition, and wherein applying the one or more PWM signals comprises applying the selected PWM parameter to all of the cooling devices.
